(19) United States
(12) Patent Application Publication
(10) Pub. No.: US 2024/0117120 A1
(43) Pub. Date: Apr. 11, 2024

(54) CURABLE RESIN COMPOSITION FOR BONDING FILM, BONDING FILM, AND PRINTED-WIRING BOARD

(71) Applicant: Shin-Etsu Chemical Co., Ltd., Tokyo (JP)

(72) Inventors: Yoshihiro TSUTSUMI, Annaka-shi (JP); Hiroyuki IGUCHI, Annaka-shi (JP)

(73) Assignee: Shin-Etsu Chemical Co., Ltd., Tokyo (JP)

(21) Appl. No.: 18/238,317

(22) Filed: Aug. 25, 2023

(30) Foreign Application Priority Data
Sep. 13, 2022 (JP) 2022-145025

(51) Int. Cl. C08G 73/12; C09J 5/06; C09J 7/28; C09J 179/08

(52) U.S. Cl. CPC C08G 73/121; C09J 5/06; C09J 7/28; C09J 179/085; C08G 2170/00; C09J 2203/326; C09J 2479/025

(57) ABSTRACT

Provided is a curable resin composition for a bonding film that has a high adhesion force to a copper foil with a small surface roughness, maintains a high adhesion force even after HAST, and can also be turned into a cured product superior in dielectric properties. The curable resin composition for a bonding film that is to be bonded to a copper foil, contains:
(A) a maleimide compound having at least one dimer acid frame-derived hydrocarbon group per molecule, that is represented by the following formula (1), (2) or (3)

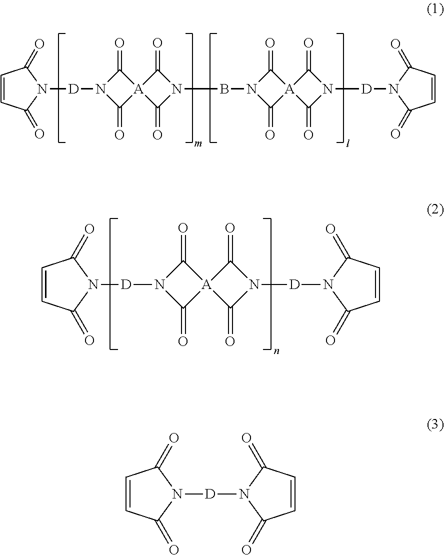

wherein A independently represents a tetravalent organic group having a cyclic structure, B independently represents a divalent hydrocarbon group having 6 to 60 carbon atoms and is a hydrocarbon group other than a dimer acid frame-derived hydrocarbon group, D represents a dimer acid frame-derived hydrocarbon group, m, l and n are each 1 to 100; and
(B) a catalyst.

### BACKGROUND OF THE INVENTION

### Field of the Invention

The present invention relates to a curable resin composition for a bonding film, a bonding film, and a printed-wiring board having such bonding film.

In recent years, a next-generation communication system known as 5G has prevailed, starting from a region of 6 GHz or lower called Sub6, exceeding a millimeterwave region of 26 to 80 GHz, and even leading up to the development of a next-next-generation communication system known as 6G, where attempts are being made to realize a communication at a higher speed, a larger capacity and a lower latency than ever before. The realization of these communication systems requires materials for use in high-frequency bands, and reduction in transmission loss is critical as a countermeasure for noise.

Transmission loss is a sum of conductor loss and dielectric loss; in order to reduce conductor loss, it is necessary to lower the roughness of the surface of a metal foil used, especially the roughness of the surface of a copper foil. Meanwhile, since dielectric loss is proportionate to a product of a square root of a relative permittivity and a dielectric tangent, it is demanded that there be developed an insulating material with excellent dielectric properties (i.e. with a low relative permittivity and a low dielectric tangent).

Particularly, in high-frequency bands, skin effect greatly affects conductor loss, which makes a material with a small surface roughness essential, and it is especially preferred that there be used a copper foil having a low surface roughness.

In order to lower dielectric loss, and as a material with a low relative permittivity and dielectric tangent, what have come into use are a reactive polyphenylene ether resin (PPE) as a heat-curable resin; and a liquid crystal polymer (LCP), a modified polyimide (MPI) with improved properties, and polytetrafluoroethylene (PTFE), as thermoplastic resins. These materials generally have a low adhesion force to a copper foil with a low surface roughness, and are thus incapable of withstanding the practical use of a low-roughness copper foil for use in high-frequency bands, which also requires an adhesive superior in dielectric properties for the purpose of supplementing the adhesion force.

In this regard, reports have been made on substantially using, as a main resin of a substrate, a dimer diamine frame-containing maleimide compound (specific maleimide compound) (WO2016/114287 and JP-A-2018-201024). As opposed to the properties of a general maleimide resin, while a specific maleimide compound has a low glass-transition temperature (Tg) and a high coefficient of thermal expansion (CTE), it also has a number of merits such as significantly excellent dielectric properties, a flexible property, an excellent adhesion force to metals or the like, and a capability of realizing multi (high)-layering as being a heat-curable resin; a wide range of researches and developments are conducted with regard to such specific maleimide compound. However, no specific studies have been made on an adhesion force to a copper foil having a surface roughness of (Ra)≈0.5 μm or lower; whether these materials can be really used for high-frequency purposes still remains unclear.

As a method(s) for producing a substrate, there are known those using build-up films (JP-A-2010-90236, JP-A-2010-90238, JP-A-2014-5464, and JP-A-2015-101626); however, these build-up films have an extremely weak adhesion force to a copper foil having a surface roughness of Ra≈0.5 μm or lower. Thus, in order to address the problem of improving the adhesiveness of a build-up film, it is necessary to either modify the build-up film itself to that having an excellent adhesiveness, or concurrently use a bonding film having an extremely high adhesion force to a copper foil.

Particularly, if used for high-frequency purposes, the surface roughness of a copper foil tends to be small, which leads to an insufficient adhesion force of a build-up film itself to such copper foil, thereby giving rise to a need for a bonding film having a high adhesion force.

Moreover, as for such adhesion force, in view of long-term reliability and occurrence of cracks in the above build-up films due to stress, needed is a material that also has excellent dielectric properties while having a high adhesion force to a copper foil having an extremely low surface roughness even when the material is in an insufficiently cured state, and having a high adhesion force even after performing HAST (Highly Accelerated Temperature and Humidity Stress Test, highly accelerated life testing); there is a strong demand for developing a material satisfying these requirements.

### SUMMARY OF THE INVENTION

Thus, it is an object of the present invention to provide a curable resin composition for a bonding film that has a high adhesion force to a copper foil with a small surface roughness which is often used for high-frequency purposes e.g. a copper foil whose Ra is 0.5 μm or lower, maintains a high adhesion force even after HAST, and can also be turned into a cured product superior in dielectric properties; a bonding film comprised of such curable resin composition; and a printed-wiring board having such bonding film.

The inventors of the present invention diligently conducted a series of studies to solve the above problems, and completed the invention by finding that the curable resin composition shown below was able to achieve the above objects.

That is, the present invention is to provide the following curable resin composition and others.

[1]

A curable resin composition for a bonding film that is to be bonded to a copper foil, comprising:
(A) a maleimide compound having at least one dimer acid frame-derived hydrocarbon group per molecule, that is represented by the following formula (1), (2) or (3)

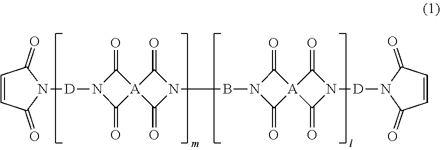

wherein A independently represents a tetravalent organic group having a cyclic structure, B independently represents a divalent hydrocarbon group having 6 to 60 carbon atoms and is a hydrocarbon group other than a dimer acid frame-derived hydrocarbon group, D represents a dimer acid frame-derived hydrocarbon group, m is 1 to 100, 1 is 1 to 100, no restrictions are imposed on an order of each repeating unit identified by m and l, and a bonding pattern may be alternate, block or random,

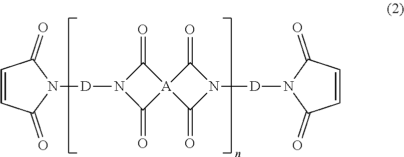

wherein A independently represents a tetravalent organic group having a cyclic structure, D represents a dimer acid frame-derived hydrocarbon group, n is 1 to 100,

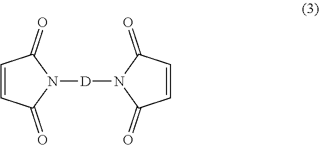

wherein D represents a dimer acid frame-derived hydrocarbon group; and
(B) a catalyst,
   wherein the maleimide compound as the component (A) contains at least two of the maleimide compounds represented by the formulae (1), (2) and (3), and at least one of the maleimide compounds represented by the formulae (1), (2) and (3) is solid at 25° C.
   [2]

The curable resin composition according to [1], wherein in the maleimide compound as the component (A), the maleimide compound that is solid at 25° C. is contained in an amount of 60 to 100% by mass.

[3]

The curable resin composition according to [1] or [2], wherein A in the formulae (1) and (2) is any one of the tetravalent organic groups represented by the following structural formulae

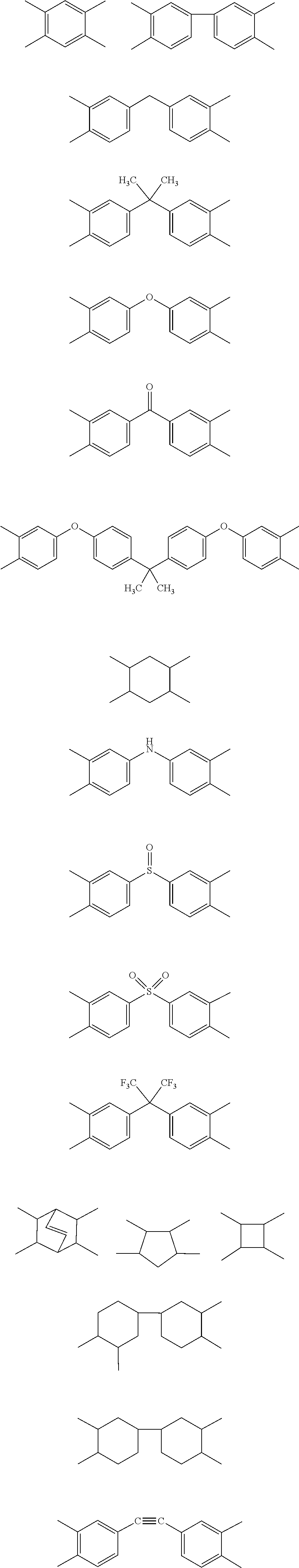

wherein bonds that are yet unbonded to substituent groups are to be bonded to carbonyl carbons forming cyclic imide structures in the formulae (1) and (2).
[4]

The curable resin composition according to any one of [1] to [3], wherein the curable resin composition is of a heat curing type.

[5]

The curable resin composition according to any one of [1] to [4], wherein the catalyst as the component (B) is at least one selected from the group consisting of a thermal radical polymerization initiator and an anionic polymerization initiator.

[6]

The curable resin composition according to [5], wherein the component (B) is an anionic polymerization initiator, and the curable resin composition further contains an epoxy resin having two or more epoxy groups per molecule.

[7]

The curable resin composition according to any one of [1] to [6], wherein a cured product of the curable resin composition has a dielectric tangent of not larger than 0.005 at 10 GHz.

[8]

The curable resin composition according to any one of [1] to [7], wherein a test piece obtained by laminating the curable resin composition on a copper foil having a surface roughness Ra of 0.17 μm, and then curing the curable resin composition by performing heating at 130° C. for 30 min and then at 170° C. for another 30 min, has a peeling strength of not lower than 0.8 kN/m between the cured product of the curable resin composition and the copper foil when measured in accordance with JIS C 6481, and has a peeling strength of not lower than 0.3 kN/m between the cured product and the copper foil after being left at 130° C. and 85% RH for 100 hours.

[9]

A bonding film comprising the curable resin composition according to any one of [1] to [8].

[10]

A printed-wiring board having the bonding film according to [9].

The curable resin composition of the present invention is such that it has a high adhesion force to a low-roughness copper foil e.g. a copper foil having a surface roughness Ra of 0.5 μm or lower, is able to maintain a high adhesion force even after HAST, and can also be turned into a cured product superior in dielectric properties. Thus, the curable resin composition of the present invention is particularly suitable for use in a bonding film used for high-frequency purposes, and is also suitable for printed-wiring board purposes.

### DETAILED DESCRIPTION OF THE INVENTION

The present invention is described in greater detail hereunder.

### (A) Maleimide Compound Having at Least one Dimer Acid Frame-Derived Hydrocarbon Group Per Molecule

A component (A) of the present invention is a maleimide compound having at least one dimer acid frame-derived hydrocarbon group per molecule, that is represented by the following formula (1), (2) or (3). Since the component (A) has a dimer acid frame-derived hydrocarbon group(s), the cured product of a composition containing such component (A) will exhibit a low relative permittivity and dielectric tangent, and there will be achieved an excellent film capability and handling property after curing the composition. Further, since the component (A) has imide groups, a high insulating property will be exhibited even after a composition containing such component (A) has been turned into a film (thin film).

Further, the maleimide compound as the component (A) contains at least two of the maleimide compounds represented by the formulae (1), (2) and (3), and at least one of the maleimide compounds represented by the formulae (1), (2) and (3) is solid at 25° C. As the component (A), by containing the maleimide compound(s) in which at least one of the maleimide compounds represented by the formula (1), (2) or (3) is solid at 25° C., the curable resin composition of the present invention will exhibit an excellent film capability and a reduced tackiness when in an uncured state, which makes the composition suitable for use as a curable resin composition for a bonding film.

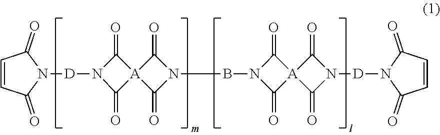

In the formula (1), A independently represents a tetravalent organic group having a cyclic structure; B independently represents a divalent hydrocarbon group having 6 to 60 carbon atoms and is a hydrocarbon group other than a dimer acid frame-derived hydrocarbon group; D represents a dimer acid frame-derived hydrocarbon group; m is 1 to 100; and 1 is 1 to 100. No restrictions are imposed on an order of each repeating unit identified by m and 1, and a bonding pattern may be alternate, block or random.

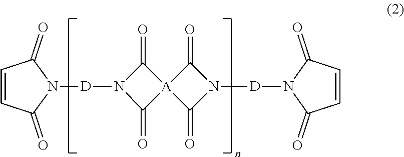

In the formula (2), A independently represents a tetravalent organic group having a cyclic structure, as is the case in the formula (1); D represents a dimer acid frame-derived hydrocarbon group, as is the case in the formula (1). n is 1 to 100.

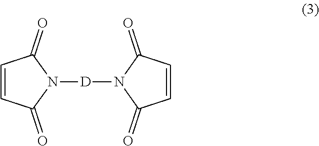

In the formula (3), D represents a dimer acid frame-derived hydrocarbon group, as is the case in the formulae (1) and (2).

A dimer acid here refers to a liquid dibasic acid whose main component is a dicarboxylic acid having 36 carbon atoms, which is produced by dimerizing an unsaturated fatty acid having 18 carbon atoms and employing a natural substance such as a vegetable fat or oil as its raw material. A dimer acid frame may contain multiple structures as opposed to one single type of frame, and there exist several types of isomers. Typical dimer acids are categorized under the names of (a) linear type, (b) monocyclic type, (c) aromatic ring type, and (d) polycyclic type. In this specification, a dimer acid frame refers to a group induced from a dimer diamine having a structure established by substituting the carboxy groups in such dimer acid with primary aminomethyl groups. That is, as the dimer acid frame-derived hydrocarbon group(s) in each molecule, it is preferred that the component (A) have a group obtained by substituting the two carboxy groups in any of the following dimer acids (a) to (d) with methylene groups.

Further, as for the dimer acid frame-derived hydrocarbon group(s) in the maleimide compound as the component (A), more preferred from the perspectives of heat resistance and reliability of a cured product are those having a structure with a reduced number of carbon-carbon double bonds in the dimer acid frame-derived hydrocarbon group(s) due to a hydrogenation reaction.

Here, in general, due to the fact that the raw material of a dimer acid is a natural substance such as a vegetable fat or oil, a trimer (trimer acid) may also be contained in a dimer acid; it is preferred when dimer acid-derived hydrocarbon groups are present at such a high ratio where they occupy, for example, 95% by mass or more of dimer acid- and trimer acid-derived hydrocarbon groups, because there will be exhibited excellent dielectric properties, an excellent moldability as viscosity will easily decrease at the time of heating, and a tendency of being less susceptible to moisture absorption. In this specification, a dimer acid (trimer acid) frame refers to a group derived from a dimer diamine (trimer triamine) having a structure established by substituting the carboxy groups in such dimer acid (trimer acid) with primary aminomethyl groups.

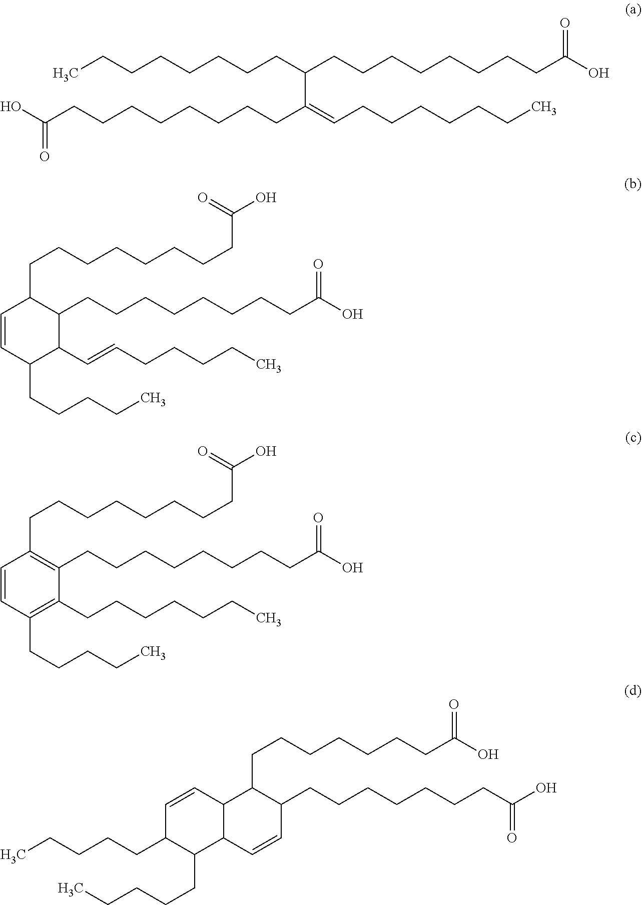 [SMILES: CCCCCCC/C=C(/CCCCCCCCC(=O)O)C(CCCCCCCC)CCCCCCCCC(=O)O ; CCCCC/C=C/C1C(CCCCC)C=CC(CCCCCCCCC(=O)O)C1CCCCCCCCC(=O)O ; CCCCCCCc1c(CCCCC)ccc(CCCCCCCCC(=O)O)c1CCCCCCCCC(=O)O ; CCCCCC1C=CC2C(C=CC(CCCCCCCC(=O)O)C2CCCCCCCC(=O)O)C1CCCCC]

As described above, since a dimer acid frame may contain multiple structures, a dimer acid frame-derived hydrocarbon group in this specification may be expressed as —C₃₆H₇₀— which is an average structure thereof.

If using the maleimide compound represented by the formula (1), there can be obtained a composition that has excellent dielectric properties before and after curing as compared to when using a general maleimide compound containing many aromatics, and has a high Tg and a high reliability for a composition containing a maleimide compound having a dimer acid frame-derived hydrocarbon group(s). In many cases, the maleimide compound represented by the formula (1) is solid at room temperature.

In the formula (1), A independently represents a tetravalent organic group having a cyclic structure; particularly, it is preferred that A be any one of the tetravalent organic groups represented by the following structural formulae.

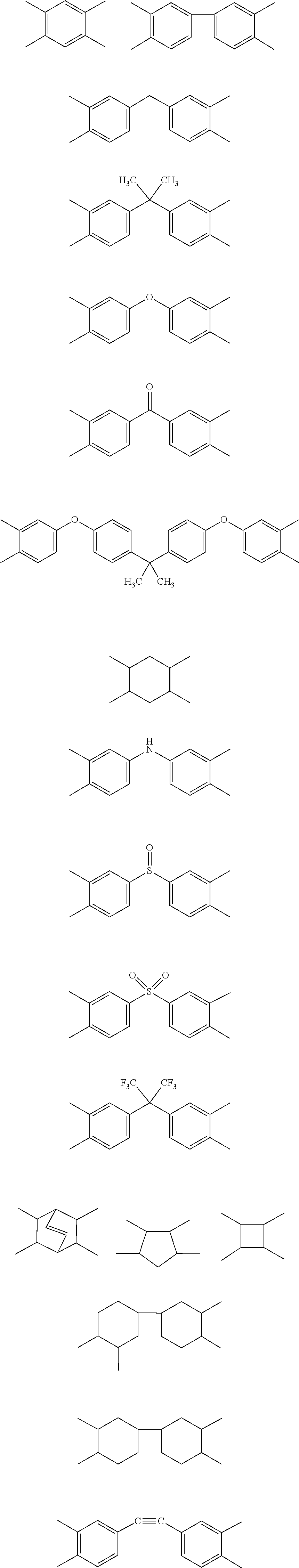

Bonds in the above structural formulae that are yet unbonded to substituent groups are to be bonded to carbonyl carbons forming cyclic imide structures in the formula (1).

In the formula (1), D represents a dimer acid frame-derived hydrocarbon group; a specific example thereof may be a group obtained by substituting the two carboxy groups in any of the dimer acids represented by the formulae (a) to (d) with methylene groups. In this specification, the dimer acid frame-derived hydrocarbon group represented by D may be expressed as —C₃₆H₇₀— which is an average structure thereof.

In the formula (1), B independently represents a divalent hydrocarbon group having 6 to 60 carbon atoms, which is a hydrocarbon group other than a dimer acid frame-derived hydrocarbon group, preferably an aromatic ring- or cyclohexane ring-containing divalent hydrocarbon group having 7 to 40 carbon atoms, more preferably an aromatic ring- or cyclohexane ring-containing divalent hydrocarbon group having 8 to 30 carbon atoms. As such cyclohexane ring-containing mode, there may be employed those having one cyclohexane ring, or those of polycyclic type with a plurality of cyclohexane rings being either bonded together via divalent groups such as alkylene groups or bridged. Specific examples of B include the divalent hydrocarbon groups represented by the following structural formulae.

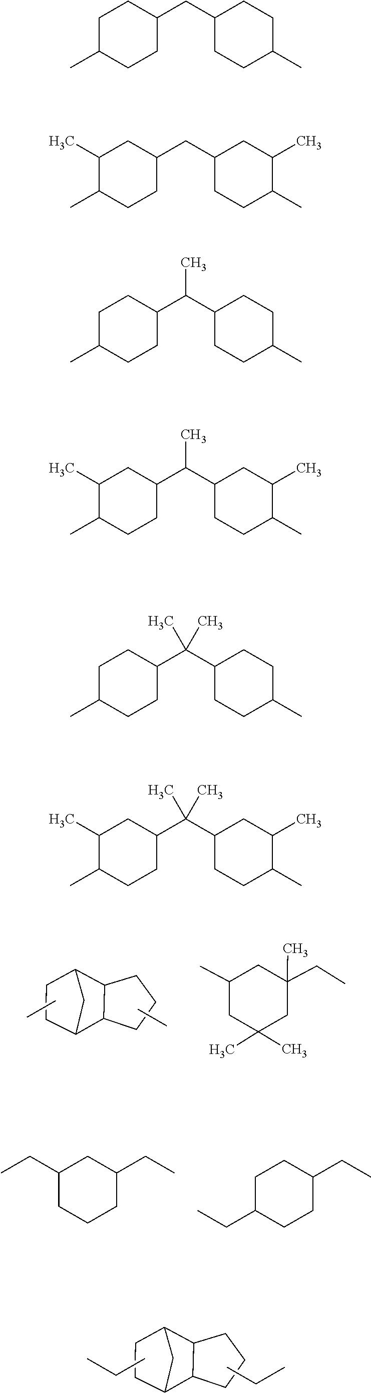

In the formula (1), m is 1 to 100, preferably 1 to 60, more preferably 2 to 50; 1 is 1 to 100, preferably 1 to 50, more preferably 3 to 40. If m and l are too large, a fluidity may be impaired, and a moldability may deteriorate.

No restrictions are imposed on the order of each repeating unit identified by m and l, and the bonding pattern may be alternate, block or random; a block bonding pattern is preferred in terms of achieving a higher Tg.

Next, if using the maleimide compound represented by the formula (2), there can be obtained a composition that has excellent dielectric properties before and after curing as compared to when using a general maleimide compound containing many aromatics; especially, the composition in such case is effective in maintaining dielectric properties even in high-frequency bands, and shall be a composition having an excellent flexibility before and after curing as compared to when using only the maleimide compound represented by the formula (1). Particularly, using the maleimide compound represented by the formula (2) is effective in terms of imparting a film capability in the uncured state.

In the formula (2), A independently represents a tetravalent organic group having a cyclic structure, as is the case with A in the formula (1); particularly, it is preferred that A be any one of the tetravalent organic groups represented by the following formulae. Depending on the structure of A in the formula (2), the property of the maleimide compound represented by the formula (2) may vary at 25° C. in a way such that the compound may be either a solid or a viscous liquid; in the combination of the component (A) employing at least two kinds thereof, the structure of the tetravalent organic group represented by A may be appropriately selected.

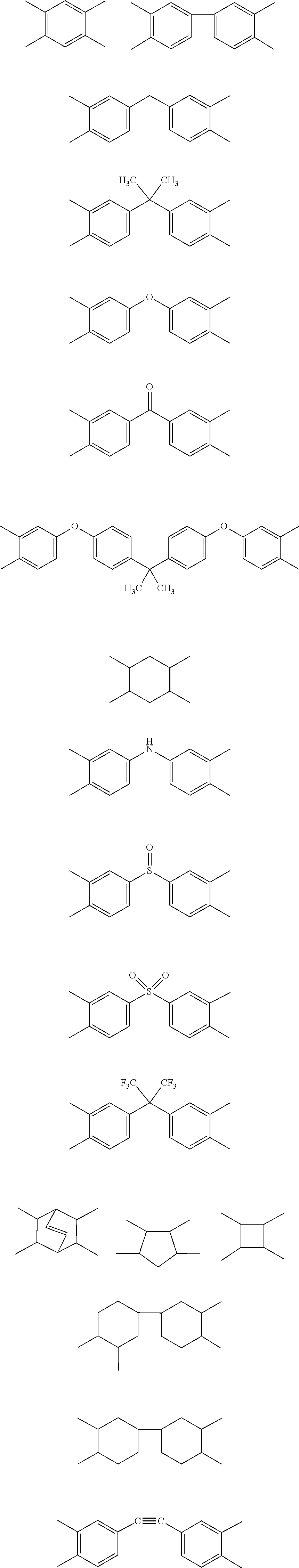

Bonds in the above structural formulae that are yet unbonded to substituent groups are to be bonded to carbonyl carbons forming cyclic imide structures in the formula (2).

In the formula (2), D represents a dimer acid frame-derived hydrocarbon group, as is the case with D in the formula (1); specifically, this hydrocarbon group may, for example, be a group obtained by substituting the two carboxy groups in any of the dimer acids represented by the above formulae (a) to (d) with methylene groups.

In the formula (2), n is 1 to 100, preferably 1 to 60, more preferably 1 to 50. If n is too large, a solubility and fluidity may be impaired, and a film-forming capability may deteriorate.

Next, the maleimide compound represented by the formula (3) is a low-viscosity liquid at room temperature (25° C.); as a result of adding this compound to a resin composition, not only an embedding property and moldability will be improved due to a decreased melt viscosity at the time of molding, but an adhesion force will be improved as well due to an improved wettability. The maleimide compound of the formula (3) has a viscosity of 1.5 to 6.0 Pa·s when measured at 25° C. and under the following measurement condition.

Measurement condition: in accordance with a method described in JIS Z8803:2011, measurement was performed at a designated measurement temperature, using a Brook field-type rotary viscometer, where a spindle rotation number is set to 5 rpm.

In the formula (3), D represents a dimer acid frame-derived hydrocarbon group, as is the case with D in the formulae (1) and (2); specifically, this hydrocarbon group may, for example, be a group obtained by substituting the two carboxy groups in any of the dimer acids represented by the above formulae (a) to (d) with methylene groups.

The curable resin composition of the present invention may also contain a maleimide compound that is different from the component (A) i.e. a maleimide compound other than any of the maleimide compounds represented by the formulae (1), (2) and (3). If containing a maleimide compound that is different from the component (A), it is preferred that the component (A) (i.e. maleimide compounds represented by the formula (1), (2) or (3)) be present at a ratio of 20 to 100% by mass, more preferably 30 to 100% by mass, even more preferably 40 to 100% by mass, per a total amount of all the maleimide compounds.

The maleimide compound as the component (A) contains at least two of the maleimide compounds represented by the formulae (1), (2) and (3), and at least one of the maleimide compounds represented by the formulae (1), (2) and (3) is solid at 25° C. For example, there may be used a combination of the maleimide compound of the formula (1) that is solid at 25° C. and the maleimide compound of the formula (2) that is liquid at 25° C.; a combination of the maleimide compound of the formula (1) that is solid at 25° C. and the maleimide compound of the formula (2) that is solid at 25° C.; or a combination of the maleimide compound of the formula (1) that is solid at 25° C. and the maleimide compound of the formula (3) that is liquid at 25° C. Further, for example, there may be used two or more kinds of the maleimide compound represented by the formula (2) that have different structures; in such case, at least one of them is solid at 25° C.

In the maleimide compound as the component (A), it is preferred that a maleimide compound(s) that is solid at 25° C. is contained in an amount of 60 to 100% by mass, more preferably 70 to 100% by mass.

### (B) Catalyst

A component (B) used in the present invention is a catalyst. Catalyst is a collective term for those capable of initiating or promoting the reaction of the maleimide groups in the maleimide compound as the component (A). There are no particular restrictions on such component (B) so long as it is able to initiate or promote the reaction of the maleimide groups in the component (A); it is preferred that there be used at least one selected from a group consisting of a thermal radical polymerization initiator and an anionic polymerization initiator.

Examples of a thermal radical polymerization initiator include an organic peroxide and an azo polymerization initiator, of which an organic peroxide is preferably used. Examples of such organic peroxide include dicumyl peroxide, t-butyl peroxybenzoate, t-amyl peroxybenzoate, dibenzoyl peroxide, dilauroyl peroxide, 2,5-dimethyl-2,5-di(t-butylperoxy)hexane, 1,1-di(t-butylperoxy)cyclohexane, di-t-butyl peroxide, dibenzoyl peroxide, and t-butylperoxy-2-ethylhexyl carbonate.

In the case of an anionic polymerization initiator, it is considered that an anionic polymerization initiator acts on the epoxy groups in a later-described epoxy resin whereafter the activated species will attack the maleimide groups to trigger anionic polymerization. Thus, if using the maleimide compound as the component (A) and an epoxy resin, it is preferred that an anionic polymerization initiator be used as the catalyst as the component (B). Examples of such anionic polymerization initiator include imidazole compounds such as imidazole, 2-methylimidazole, 2-ethylimidazole, 2-heptadecylimidazole, 1,2-dimethylimidazole, 2-ethyl-4-methylimidazole, 2-undecylimidazole, 2-phenylimidazole, 2-phenyl-4-methylimidazole, 1-benzyl-2-methylimidazole, 1-cyanoethyl-2-methylimidazole, 1-cyanoethyl-2-ethyl-4-methylimidazole, 1-cyanoethyl-2-undecylimidazole, 1-cyanoethyl-2-phenylimidazole, 2-phenyl-4,5-dihydroxymethylimidazole, and 2-phenyl-4-methyl-5-hydroxymethylimidazole; organic phosphorus compounds such as tributylphosphine, tri(p-methylphenyl)phosphine, tri(nonylphenyl)phosphine, triphenylphosphine, triphenylphosphine oxide, triphenylphosphine-triphenylborane, and tetraphenylphosphine-tetraphenylborate; and tertiary amine compounds such as triethylamine, benzyldimethylamine, α-methylbenzyldimethylamine, 1,8-diazabicyclo [5.4.0]undecene, and tris(dimethylaminomethyl)phenol.

The catalyst as the component (B) is preferably contained in an amount of 0.1 to 5.0 parts by mass, more preferably 0.2 to 4.5 parts by mass, even more preferably 0.5 to 4.0 parts by mass, per 100 parts by mass of the component (A). Curing may proceed slowly if the component (B) is added in an amount of smaller than 0.1 parts by mass per 100 parts by mass of the component (A); and the composition may lack preservation stability if the component (B) is added in an amount of larger than 5.0 parts by mass per 100 parts by mass of the component (A). Further, one kind of the component (B) may be used alone, or two or more kinds thereof may be used in a mixed manner; for example, a thermal radical polymerization initiator and an anionic polymerization initiator may be used in combination.

### Other Additives

If necessary, the curable resin composition of the present invention may further contain various additives within the scope of not impairing the effects of the present invention. These additives are exemplified below.

### Epoxy Resin

In order to improve the properties of the curable resin composition of the present invention, the composition of the invention may further contain an epoxy resin. There are no particular restrictions on such epoxy resin used so long as it has two or more epoxy groups per molecule. Specific examples of the epoxy resin include a bisphenol A-type epoxy resin; a bisphenol F-type epoxy resin; a biphenol-type epoxy resin such as 3,3′,5,5′-tetramethyl-4,4′-biphenol type epoxy resin and 4,4′-biphenol type epoxy resin; a phenol novolac-type epoxy resin; a cresol novolac-type epoxy resin; a bisphenol A novolac-type epoxy resin; a naphthalenediol-type epoxy resin; a trisphenol methane-type epoxy resin; a trisphenylol methane-type epoxy resin; tetrakisphenylol ethane-type epoxy resin; a phenol biphenyl-type epoxy resin; a dicyclopentadiene-type epoxy resin; a biphenyl aralkyl-type epoxy resin; an epoxy resin prepared by hydrogenating the aromatic ring of a phenol dicyclopentadiene novolac-type epoxy resin; a triazine derivative epoxy resin; and an alicyclic epoxy resin.

If an epoxy resin is added and an anionic polymerization initiator is used as the catalyst as the component (B), it is preferred that the epoxy resin be present at a ratio of 0.1 to 100 parts by mass, more preferably 0.1 to 50 parts by mass, per 100 parts by mass of the component (A), and it is preferred that the anionic polymerization initiator is added in an amount of 0.1 to 5.0 parts by mass, more preferably 0.2 to 4.5 parts by mass, even more preferably 0.5 to 4.0 parts by mass, per 100 parts by mass of the component (A).

### Inorganic Filler

In the present invention, there may further be added an inorganic filler if necessary. An inorganic filler is added to improve the strength and rigidity of the cured product of the curable resin composition of the present invention, or adjust a thermal expansion coefficient and the dimension stability of the cured product. As such inorganic filler, there may be used those that are generally added to an epoxy resin composition or a silicone resin composition. There may be listed, for example, silicas such as a spherical silica, a molten silica and a crystalline silica; alumina; silicon nitride; aluminum nitride; boron nitride; barium sulfate; talc; clay; aluminum hydroxide; magnesium hydroxide; calcium carbonate; glass fibers; and glass particles. Further, for the sake of improving dielectric properties, there may also be used a fluorine-containing resin filler, a coating filler and/or hollow particles; and for the sake of for example imparting an electric conductivity, there may also be added metal particles, metal-coated inorganic particles, carbon fibers and carbon nanotubes. One kind of such inorganic filler may be used alone, or two or more kinds thereof may be used in combination. The inorganic filler may be added in an amount of 0 to 400 parts by mass, preferably 0 to 300 parts by mass, per 100 parts by mass of the component (A).

There are no particular restrictions on the average particle size and shape of the inorganic filler; in order to turn the curable resin composition of the present invention into a bonding film, particularly preferred is a spherical silica having an average particle size of 0.5 to 5 μm. Here, an average particle size is a value obtained as a mass average value D₅₀ (or median size) in a particle size distribution measurement conducted by a laser diffraction method.

Further, for the sake of property improvement, it is preferred that the inorganic filler be one that has already been surface-treated with a silane coupling agent having organic groups capable of reacting with reactive groups such as the abovementioned maleimide groups. Examples of such silane coupling agent include an epoxy group-containing alkoxysilane, an amino group-containing alkoxysilane, a (meth)acryloyl group-containing alkoxysilane, and an alkenyl group-containing alkoxysilane, as mentioned above.

### Others

In addition to the above additives, there may also be added, for example, a thermoplastic resin such as a styrene-ethylene-butadiene-styrene block copolymer (SEBS), a thermoplastic elastomer, an organic synthetic rubber, a non-functional silicone oil, a reactive diluent, a photosensitizer, a light stabilizer, a polymerization inhibitor, an antioxidant, a flame retardant, a pigment, a dye, an adhesion aid, and an ion-trapping agent.

Further, any of the above silane coupling agents such as an epoxy group-containing alkoxysilane, an amino group-containing alkoxysilane, a (meth)acryloyl group-containing alkoxysilane and an alkenyl group-containing alkoxysilane that are used for surface-treating the inorganic filler, may be separately added to the curable resin composition of the present invention as a type of adhesion aid.

In terms of its intended use, it is preferred that the cured product of the curable resin composition of the present invention have a low relative permittivity and dielectric tangent; as described above, it is particularly preferred that the cured product have a low dielectric tangent as dielectric loss is proportionate to the product of a square root of relative permittivity and dielectric tangent. Specifically, it is preferred that the cured product of the curable resin composition of the present invention have a dielectric tangent of not larger than 0.005, more preferably not larger than 0.004, at 10 GHz.

### Bonding Film

The curable resin composition of the present invention is one that is favorably used to produce a bonding film. A bonding film comprised of the curable resin composition of the present invention may be produced by a process where the composition is at first dissolved in an organic solvent to prepare a varnish, followed by applying the varnish to a base material and then volatilizing the organic solvent; or a process where the components are to be preliminarily mixed together in advance without using an organic solvent, followed by using a melting and kneading machine to push out the mixture into the shape of a sheet or film. Further, after turning the composition into a varnish, this varnish may then be applied to and/or used to impregnate a glass cloth made of an E glass, a low-dielectric glass, a quartz glass or the like, followed by drying the organic solvent to obtain a prepreg in which the curable resin composition has been turned into a semi-cured state, whereby this prepreg may then be used as a bonding film.

There are no restrictions on the organic solvent; any organic solvent may be used so long as the curable resin as the component (A) can be dissolved therein. For example, there may be listed a ketone-based organic solvent such as methyl ethyl ketone (MEK) and methyl isobutyl ketone (MIBK); a hydrocarbon-based organic solvent such as tetralin, mesitylene, xylene and toluene; anisole; tetrahydrofuran (THF); dimethylformamide (DMF); dimethylsulfoxide (DMSO); and acetonitrile. Here, preferred are aromatic organic solvents such as anisole, tetralin, mesitylene, xylene and toluene. Any one kind of these organic solvents may be used alone, or two or more kinds of them may be used in combination.

Such resin composition in the form of a varnish (i.e. resin varnish) may, for example, be prepared as follows. At first, components in the composition of the resin composition that are soluble in the organic solvent are to be added to the organic solvent to dissolve them. At that time, heating may also be performed if necessary. Next, components that are insoluble in the organic solvent, such as the inorganic filler used as needed are added, followed by using a ball mill, a bead mill, a planetary mixer, a roll mill or the like to disperse them until a given dispersed state has been reached, thereby obtaining the resin composition in the form of a varnish.

Next, for example, after applying to a base material the curable resin composition dissolved in the organic solvent (i.e. varnish), the organic solvent is eliminated by performing heating at a temperature of normally not lower than 80° C., preferably not lower than 100° C. for 0.5 to 20 min, thereby allowing a bonding film to be produced. The temperature in the drying step for eliminating the organic solvent and the temperature in the subsequent heating and curing step may each be a constant temperature; it is preferred that these temperatures be raised in a step-wise manner. Thus, not only the organic solvent can be efficiently eliminated out of the composition, but the curing reaction of the resins can also take place efficiently. Examples of a method for applying the varnish may include those employing a spin coater, a slit coater, a sprayer, a dip coater, a bar coater, and a die coater; there are no particular restrictions on such method.

As a coating base material, there may be used a general resin base material, examples of which include polyolefin resins such as a polyethylene (PE) resin, a polypropylene (PP) resin and a polystyrene (PS) resin; and polyester resins such as a polyethylene terephthalate (PET) resin, a polybutylene terephthalate (PBT) resin and a polycarbonate (PC) resin. The surface of such base material may also be subjected to a mold release treatment. Further, there are no particular restrictions on the thickness of a coating layer (curable resin composition); a thickness after distilling away the solvent is 1 to 200 μm, preferably 3 to 150 μm. A cover film may also be provided on such coating layer.

The thickness of the bonding film comprised of the curable resin composition is normally in a range of 1 to 300 μm, preferably 3 to 200 μm in terms of handling property, production method, and stability in adhesion force.

### Prepreg

A prepreg has the curable resin composition or a semi-cured product thereof, and a glass cloth. Here, a semi-cured product refers to a product of a state where the resin composition has been incompletely cured to the extent that the composition can actually be further cured. That is, the semi-cured product is a product of a state where the resin composition has been semi-cured i.e. a B-staged product. Meanwhile, an uncured state may also be referred to as A-stage. That is, the curable resin composition in the prepreg may be in the state of A-stage, or in the state of B-stage. As for the glass cloth, there may be listed, for example, an E glass, a low-dielectric glass, a quartz glass, or even an S glass and a T glass, as mentioned above; while any type of glass may be used, a quartz glass cloth having low dielectric properties is preferred in terms of taking advantage of the properties of the curable resin composition. Here, the thickness of a generally used glass cloth is, for example, not smaller than 0.01 mm and not larger than 0.3 mm.

When producing a prepreg, a curable resin composition is often turned into the form of a varnish before use as described above so that a glass cloth as a base material for forming the prepreg can be impregnated therewith. That is, normally, a curable resin composition is often a resin varnish prepared in the form of a varnish, and the production method thereof may, for example, be the abovementioned method.

After impregnating the glass cloth with the curable resin composition prepared in the form of a varnish, the organic solvent is usually dried. The glass cloth is to be impregnated with the curable resin composition by, for example, dipping the glass cloth into the curable resin composition and/or applying the curable resin composition to the glass cloth. If necessary, dipping and/or application may be repeated multiple times to impregnate the glass cloth with the curable resin composition. Further, at that time, by repeating impregnation using multiple resin compositions having different compositions and concentrations, the composition and impregnation amount can also be eventually adjusted to desired ones. The glass cloth impregnated with the resin composition(s) (i.e. resin varnish) is heated under a desired heating condition; for example, it is heated at a temperature of 80 to 180° C. for 1 to 20 min. By performing heating, there can be obtained an uncured (A-staged) or semi-cured (B-staged) prepreg. Here, by performing such heating process, the organic solvent can be volatilized from the resin varnish, and the organic solvent can thus be reduced or eliminated.

### Printed-Wiring Board

A printed-wiring board of the present invention is one having the aforementioned bonding film. Further, a base material used in the printed-wiring board is a copper foil, and preferred is a copper foil having a low surface roughness Ra in terms of conductor loss. As described later, the curable resin composition of the present invention particularly has a high initial adhesion force with respect to a copper foil having an extremely low surface roughness Ra of 0.17 μm, and is able to maintain a high adhesion force even after HAST.

A rough index of the adhesion force is as follows: the curable resin composition of the present invention is to be laminated on a copper foil having a surface roughness Ra of 0.17 μm, whereafter the laminate is heated at 130° C. for 30 min, and then at 170° C. for another 30 min to cure the curable resin composition so as to obtain a test piece; a peeling strength (initial adhesion force) between the cured product of the curable resin composition and the copper foil that is measured in accordance with JIS C 6481 is preferably not lower than 0.8 kN/m, and a peeling strength (adhesion force after HAST) between the cured product and the copper foil that is measured after leaving the test piece at 130° C. and 85% RH for 100 hours is preferably not lower than 0.3 kN/m.

Here, the surface roughness Ra of the copper foil is a value measured in accordance with JIS B 0601-2001.

The process of laminating the curable resin composition on the copper foil may be a method where lamination is carried out utilizing a roll, a pressing pressure or the like. Particularly, a vacuum lamination method is favorably employed. Further, the lamination method may be performed either in a batch-wise or a continuous manner.

As a vacuum laminator, there may be used a commercially available vacuum laminator, and a heating temperature is preferably 40 to 160° C.; when the heating temperature is within this range, although the curable resin composition will soften, flow-out will not occur so that the curable resin composition can be easily press-bonded to the base material. Further, the temperatures of the top and bottom layers of the laminator may be set differently. Further, a press-bonding pressure is preferably 0.1 to 1.5 MPa; when the press-bonding pressure is within this range, the resin composition can be press-bonded to the base material without flowing out. Here, it is preferred that lamination be performed under a reduced air pressure of 30 hPa or lower.

As for lamination to a surface that is different from the lamination surface of the curable resin composition to the copper foil, there may be used a method similar to the one described above. When laminating, several pieces of the curable resin composition film may be simultaneously stacked together, or a support-equipped curable resin composition may be further stacked on a laminate with the curable resin composition already stacked on the base material. Further, the curable resin composition may also be in the state of the aforementioned prepreg that contains the glass cloth.

As for the curing type of the curable resin composition, heat curing is preferred in terms of improving the adhesion force, and workability. Although the condition varies depending on, for example, the type of the component (B) used, the curable resin composition is normally cured at a curing temperature of 120 to 200° C. for a curing time of 15 to 600 min. However, in the present invention, measured is the peeling strength after curing the composition by performing heating at 130° C. for 30 min and then at 170° C. for another 30 min, thereby allowing the adhesion force of the curable resin composition to be measured. Here, in an actual production process of a printed-wiring board, curing condition(s) other than those described above may be employed; the laminate may be cured by or without being further pressurized.

### WORKING EXAMPLES

The present invention is described in detail hereunder with reference to working and comparative examples; the present invention shall not be limited to the following working examples.

Components used in the working and comparative examples are as follows.
(A-1) Maleimide Compound
(A-1-1): Bismaleimide compound represented by the following formula (BMI-2500 by Designer Molecules Inc., solid at 25° C.)

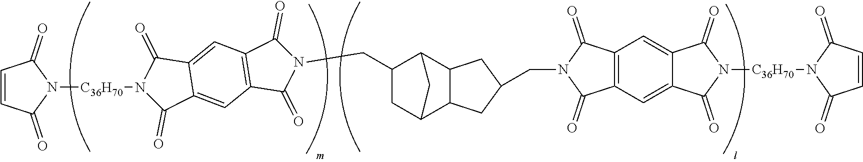

—C₃₆H₇₀— represents a dimer acid frame-derived hydrocarbon group.
1≈5 (Average value), m≈1 (Average value)
(A-1-2): Bismaleimide compound represented by the following formula (BMI-1500 by Designer Molecules Inc., viscous liquid at 25° C.)

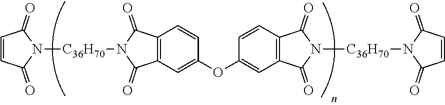

—C₃₆H₇₀— represents a dimer acid frame-derived hydrocarbon group.
n≈2 (Average value)
(A-1-3): Bismaleimide compound represented by the following formula (BMI-5000 by Designer Molecules Inc., solid at 25° C.)

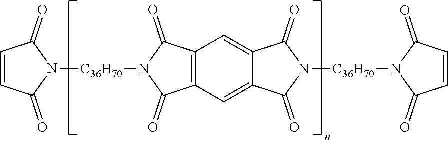

—C₃₆H₇₀— represents a dimer acid frame-derived hydrocarbon group.
n≈8 (Average value)
(A-1-4): Bismaleimide compound represented by the following formula (BMI-689 by Designer Molecules Inc., liquid at 25° C., 1.5 Pa·s)

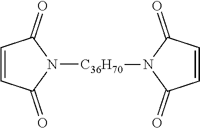

### Other Resins

(A-2-1): Bismaleimide compound represented by the following formula (BMI-6100 by Designer Molecules Inc.)

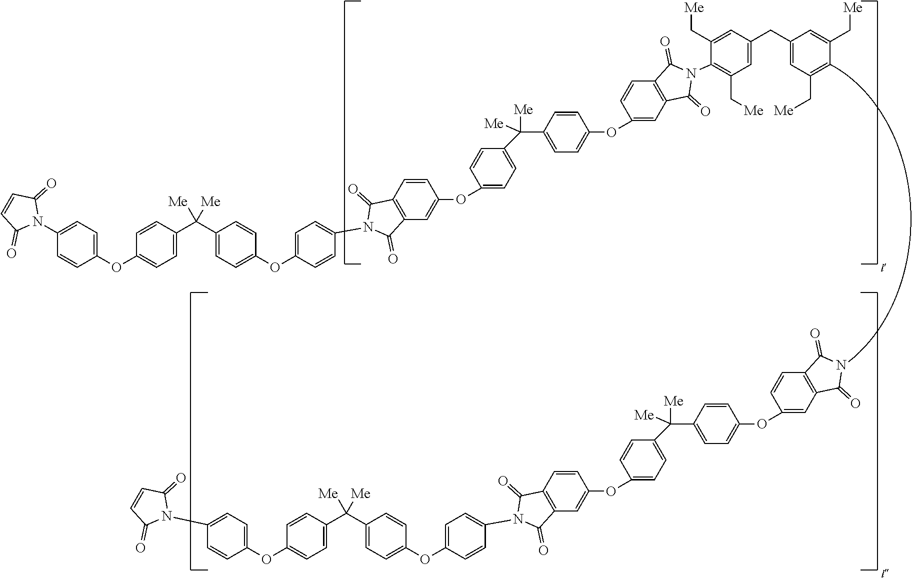

1′≈1 (Average value), 1″≈10 (Average value)
(A-2-2): 4,4′-diphenylmethanebismaleimide (BMI-1000, Daiwakasei Industry Co., LTD.)
(A-2-3): Crystalline bisphenol A-type epoxy resin (YL-6810 by Mitsubishi Chemical Corporation, epoxy equivalent 170)
(A-2-4): Solid bisphenol A-type epoxy resin (jER-1001 by Mitsubishi Chemical Corporation, epoxy equivalent 475, softening point 64° C.)
(A-2-5): Trisphenol methane-type epoxy resin (EPPN-501S by Nippon Kayaku Co., Ltd., epoxy equivalent 166, softening point 54° C.)
(A-2-6): Trisphenol methane-type phenolic resin (MEH-7500 by Meiwa Plastic Industries, Ltd., hydroxyl equivalent 97)
(A-2-7): Active ester compound (EXB9460S-65T by DIC Corporation, active ester equivalent 223, toluene solution with a solid content of 65% by mass)

### (B) Catalyst

(B-1): Dicumylperoxide (Perkadox BC-FF by KAYAKU NOURYON CORPORATION, one-hour half-life temperature 137° C.)
(B-2): t-butylperoxy-2-ethylhexyl carbonate (Trigonox 117 by KAYAKU NOURYON CORPORATION, one-hour half-life temperature 117° C.)
(B-3): 2-phenyl-4,5-dihydroxymethylimidazole (2PHZ-PW by SHIKOKU KASEI HOLDINGS CORPORATION)
(B-4): Triphenylphosphine (TPP by HOKKO CHEMICAL INDUSTRY CO., LTD.)

### (C) Inorganic Filler

(C-1): Toluene slurry of spherical silica having an average particle size of 0.5 μm (5SV-CT1 by ADMATECHS COMPANY LIMITED, solid concentration 75% by mass)

### Preparation of Resin Varnish

At the compounding ratios shown in Tables 1 and 2, the components listed in these tables were put into a 500 mL four-necked flask equipped with a Dimroth condenser and a stirrer. A resin composition in the form of a varnish (i.e. resin varnish) was obtained by performing stirring at 80° C. for 2 hours. Here, evaluation was not conducted with regard to comparative examples 3 and 5; this was because in these comparative examples, although the organic solvent was eliminated to turn the resin composition into a film, the composition remained as a liquid, which made it impossible to handle it as a film. Evaluation was not conducted with regard to comparative example 9 either, because separation was observed in the varnish even though the resin components had all dissolved.

### Production of Uncured Resin Film

As for the examples where the resin varnish was able to be produced unproblematically by the above process, a roller coater was used to apply the resin varnish to a PET film that had been subjected to a mold release treatment and had a thickness of 50 μm (TN-010 by TOYOBO STC CO, LTD), followed by drying the same at 120° C. for 10 min to obtain an uncured resin film having a thickness of 50 μm.

### Peeling Strength

There was used a SUS 304 plate having a length of 75 mm, a width of 25 mm and a thickness of 1.0 mm. The uncured resin film with the PET film was then placed on one surface of such SUS 304 plate so that the resin film surface thereof would come into contact with the one surface of the SUS 304 plate, followed by performing lamination at 100° C. and 0.3 MPa for 60 sec. After the lamination was over, the PET film was removed, and an 18 μm-thick copper foil (Ra: 0.17 μm) was then placed on and brought into contact with the resin film surface exposed, followed by performing lamination at 100° C. and 0.3 MPa for 60 sec. After the lamination was over, an adhesion test piece was produced by curing the laminated product at 130° C. for 30 min and then at 170° C. for another 30 min. In order to evaluate adhesiveness, there was measured a 90° peeling adhesion strength (kN/m) when peeling the copper foil of each adhesion test piece from a glass slide at a temperature of 23° C. and a tension rate of 50 mm/min, in accordance with JIS-C-6481 “Test methods of copper-clad laminates for printed wiring boards.” In addition, after leaving the adhesion test piece prepared by the above method at 130° C. and 85% RH for 100 hours, there was again likewise measured the 90° peeling adhesion strength (kN/m) when peeling the copper foil of each adhesion test piece from the glass slide at the temperature of 23° C. and the tension rate of 50 mm/min, in accordance with JIS-C-6481 “Test methods of copper-clad laminates for printed wiring boards.”

### Relative Permittivity, Dielectric Tangent

The uncured resin film was directly fixed on a flat plate together with the PET film that had been subjected to a mold release treatment, followed by performing heating at 130° C. for 30 min and then at 170° C. for another 30 min to cure the resin film so as to obtain a cured resin film. A network analyzer (E5063-2D5 by Keysight Technologies) and a stripline (by KEYCOM Corporation) were connected to measure a relative permittivity and dielectric tangent of the cured resin film at a frequency of 10 GHz.

TABLE 1

| Composition table | | | Working example | | | | | | | | | | |
|---|---|---|---|---|---|---|---|---|---|---|---|---|---|
| (part by mass) | | | 1 | 2 | 3 | 4 | 5 | 6 | 7 | 8 | 9 | 10 | 11 |
| (A) | BMI-2500 | A-1-1 | 80.0 | | | 50.0 | 80.0 | 80.0 | 80.0 | 80.0 | | | |
| | BMI-1500 | A-1-2 | 20.0 | 20.0 | 10.0 | | 20.0 | 20.0 | 20.0 | 20.0 | 20.0 | 20.0 | 20.0 |
| | BMI-5000 | A-1-3 | | 80.0 | 80.0 | 50.0 | | | | | 80.0 | 75.0 | 80.0 |
| | BMI-689 | A-1-4 | | | 10.0 | | | | | | | | |
| | BMI-6100 | A-2-1 | | | | | | | | | | 5.0 | |
| | BMI-1000 | A-2-2 | | | | | | | | | | | |
| | YL-6810 | A-2-3 | | | | | | | | | | | |
| | jER-1001 | A-2-4 | | | | | | | 5.0 | 5.0 | 5.0 | 5.0 | |
| | EPPN-501S | A-2-5 | | | | | | | | | | | 5.0 |
| | MEH-7500 | A-2-6 | | | | | | | | | | | |
| | EXB9460S-65T | A-2-7 | | | | | | | | | | | |
| (B) | Perkadox BC-FF | B-1 | 1.0 | 1.0 | 1.0 | 1.0 | | 1.0 | | | | | |
| | Trigonox 117 | B-2 | | | | | 1.0 | | | | | | |
| | 2PHZ-PW | B-3 | | | | | | | 1.0 | 1.0 | 1.0 | 1.0 | 1.0 |
| | TPP | B-4 | | | | | | | | | | | |
| (C) | 5SV-CT1 * | C-1 | | | | | | 133.3 | | 133.3 | | | |
| | | | | | | | | (100.0) | | (100.0) | | | |
| (Solvent) | Anisole | | 80.0 | 80.0 | 80.0 | 80.0 | 80.0 | 70.0 | 80.0 | 70.0 | 80.0 | 80.0 | 80.0 |
| | Toluene | | | | | | | | | | | | |
| Evaluation | Initial peeling | kN/m | 1.1 | 1.3 | 1.3 | 1.2 | 1.3 | 1.1 | 1.3 | 1.1 | 1.5 | 1.0 | 1.4 |
| results | strength | | | | | | | | | | | | |
| | Peeling strength | kN/m | 0.3 | 0.4 | 0.6 | 0.4 | 0.3 | 0.5 | 0.5 | 0.7 | 0.6 | 0.3 | 0.4 |
| | after HAST | | | | | | | | | | | | |
| | 10 GHz Relative | | 2.52 | 2.47 | 2.48 | 2.50 | 2.55 | 2.92 | 2.61 | 2.92 | 2.55 | 2.69 | 2.63 |
| | ermittivity | | | | | | | | | | | | |
| | 10 GHz Dielectric | | 0.0019 | 0.0017 | 0.0021 | 0.0018 | 0.0020 | 0.0013 | 0.0022 | 0.0015 | 0.0020 | 0.0028 | 0.0020 |
| | tangent | | | | | | | | | | | | |

* Numerical value in parenthesis of component C indicates number of parts of an actual amount of the inorganic filler.

TABLE 2

| Composition table | | | Comparative example | | | | | | | |
|---|---|---|---|---|---|---|---|---|---|---|
| (part by mass) | | | 1 | 2 | 3 | 4 | 5 | 6 | 7 | 8 |
| (A) | BMI-2500 | A-1-1 | 100 | 100 | | | | | | |
| | BMI-1500 | A-1-2 | | | 100 | | | | | |
| | BMI-5000 | A-1-3 | | | | 100 | 100 | | | |
| | BMI-689 | A-1-4 | | | | | | 100 | | |
| | BMI-6100 | A-2-1 | | | | | | | 100 | 100 |
| | BMI-1000 | A-2-2 | | | | | | | | |
| | YL-6810 | A-2-3 | | | | | | | | |
| | jER-1001 | A-2-4 | | 5.0 | | | 5.0 | | | 5.0 |
| | EPPN-501S | A-2-5 | | | | | | | | |
| | MEH-7500 | A-2-6 | | | | | | | | |
| | EXB9460S-65T ** | A-2-7 | | | | | | | | |
| (B) | Perkadox | B-1 | 1.0 | | 1.0 | 1.0 | | 1.0 | 1.0 | |
| | BC-FF | | | | | | | | | |
| | Trigonox 117 | B-2 | | | | | | | | |
| | 2PHZ-PW | B-3 | | 1.0 | | | 1.0 | | | 1.0 |
| | TPP | B-4 | | | | | | | | |
| (C) | 5SV-CT1 *** | C-1 | | | | | | | | |
| (Solvent) | Anisole | | 80.0 | 80.0 | 80.0 | 80.0 | 80.0 | 80.0 | 150.0 | 150.0 |
| | Toluene | | | | | | | | | |
| Evaluation | Initial peeling | kN/m | 0.9 | 0.9 | Not | 1.4 | 1.6 | Not | <0.1 | 0.3 |
| results | strength | | | | evaluated | | | evaluated | | |
| | Peeling | kN/m | <0.1 | <0.1 | | <0.2 | <0.2 | | <0.1 | <0.1 |
| | strength | | | | | | | | | |
| | after HAST | | | | | | | | | |
| | 10 GHz Relative | | 2.50 | 2.55 | | 2.46 | 2.50 | | 2.82 | 2.91 |
| | ermittivity | | | | | | | | | |
| | 10 GHz | | 0.0018 | 0.0023 | | 0.0013 | 0.0018 | | 0.0070 | 0.0081 |
| | Dielectric | | | | | | | | | |
| | tangent | | | | | | | | | |

| | |
|---|---|
| Composition table | Comparative example |

| (part by mass) | | | 9 | 10 | 11 | 12 | 13 | 14 | 15 | 16 |
|---|---|---|---|---|---|---|---|---|---|---|
| (A) | BMI-2500 | A-1-1 | | | | | | | | |
| | BMI-1500 | A-1-2 | | | | | | | | |
| | BMI-5000 | A-1-3 | 80 | | | | | | | |
| | BMI-689 | A-1-4 | | | | | | | | |
| | BMI-6100 | A-2-1 | | | | | | | | |
| | BMI-1000 | A-2-2 | | | | | | | | |
| | YL-6810 | A-2-3 | 20 | 16.0 | 16.0 | 25.5 | 25.5 | | | 13.9 |
| | jER-1001 | A-2-4 | | | | | | | | |
| | EPPN-501S | A-2-5 | | 47.5 | 47.5 | 38.0 | 38.0 | 43.9 | 43.9 | 30.0 |
| | MEH-7500 | A-2-6 | | 36.5 | 36.5 | 36.5 | 36.5 | | | |
| | EXB9460S-65T ** | A-2-7 | | | | | | 86.3 | 86.3 | 86.3 |
| | | | | | | | | (56.1) | (56.1) | (56.1) |
| (B) | Perkadox | B-1 | 1.0 | | | | | | | |
| | BC-FF | | | | | | | | | |
| | Trigonox 117 | B-2 | | | | | | | | |
| | 2PHZ-PW | B-3 | | 1.0 | 1.0 | 1.0 | | 1.0 | 1.0 | 1.0 |
| | TPP | B-4 | | | | | 1.5 | | | |
| (C) | 5SV-CT1 *** | C-1 | | | 133.3 | | | | 133.3 | |
| | | | | | (100.0) | | | | (100.0) | |
| (Solvent) | Anisole | | 125 | | | 100.0 | 100.0 | | | |
| | Toluene | | | 120.0 | 120.0 | | | 70.0 | 30.0 | 70.0 |
| Evaluation | Initial peeling | kN/m | Not | 0.9 | 0.3 | 0.6 | 0.5 | 0.7 | 0.5 | 0.7 |
| results | strength | | evaluated | | | | | | | |
| | Peeling | kN/m | | <0.2 | <0.1 | <0.1 | <0.1 | <0.2 | <0.1 | <0.2 |
| | strength | | | | | | | | | |
| | after HAST | | | | | | | | | |
| | 10 GHz Relative | | | 3.90 | 3.82 | 3.91 | 3.92 | 3.12 | 3.34 | 3.19 |
| | ermittivity | | | | | | | | | |
| | 10 GHz | | | 0.0291 | 0.0218 | 0.0286 | 0.0284 | 0.0122 | 0.0101 | 0.0125 |
| | Dielectric | | | | | | | | | |
| | tangent | | | | | | | | | |

** Numerical value in parenthesis of component A-2-7 indicates number of parts of active ester compound.
*** Numerical value in parenthesis of component C indicates number of parts of an actual amount of the inorganic filler.

In the comparative examples 1 to 6 and 9 where the composition contained only one kind of maleimide compound as the component (A), either the composition was unable to be turned into a film; or even when the composition was able to be turned into a film, a poor adhesion force was exhibited as indicated by a low peeling strength after HAST. Further, in the comparative examples 7 to 8 and 10 to 16 where the composition contained no maleimide compound as the component (A), the initial peeling strength was low, and the peeling strength after HAST was also low.

In contrast, in the working examples 1 to 11, the composition was able to be turned into a film; with respect to a copper foil having a low surface roughness Ra of 0.17 μm, the initial peeling strength was high, and a high peeling strength was able to be maintained even after performing HAST; and the cured product exhibited excellent dielectric properties. Thus, it was confirmed that the curable resin composition of the present invention was useful as a curable resin composition for a bonding film that is to be bonded to a copper foil and is used for high-frequency purposes.

What is claimed is:

1. A curable resin composition for a bonding film that is to be bonded to a copper foil, comprising:
(A) a maleimide compound having at least one dimer acid frame-derived hydrocarbon group per molecule, that is represented by the following formula (1), (2) or (3) 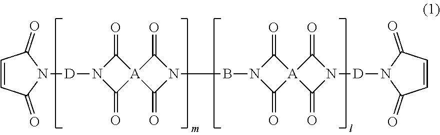
wherein A independently represents a tetravalent organic group having a cyclic structure, B independently represents a divalent hydrocarbon group having 6 to 60 carbon atoms and is a hydrocarbon group other than a dimer acid frame-derived hydrocarbon group, D represents a dimer acid frame-derived hydrocarbon group, m is 1 to 100, 1 is 1 to 100, no restrictions are imposed on an order of each repeating unit identified by m and l, and a bonding pattern may be alternate, block or random, 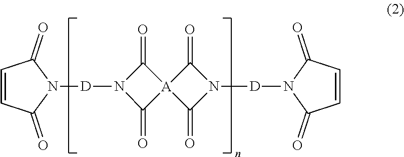
wherein A independently represents a tetravalent organic group having a cyclic structure, D represents a dimer acid frame-derived hydrocarbon group, n is 1 to 100, 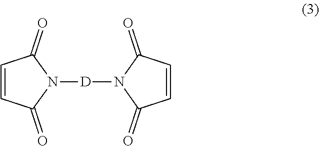
wherein D represents a dimer acid frame-derived hydrocarbon group; and
(B) a catalyst,
wherein the maleimide compound as the component (A) contains at least two of the maleimide compounds represented by the formulae (1), (2) and (3), and at least one of the maleimide compounds represented by the formulae (1), (2) and (3) is solid at 25° C.

2. The curable resin composition according to claim 1, wherein in the maleimide compound as the component (A), the maleimide compound that is solid at 25° C. is contained in an amount of 60 to 100% by mass.

3. The curable resin composition according to claim 1, wherein A in the formulae (1) and (2) is any one of the tetravalent organic groups represented by the following structural formulae 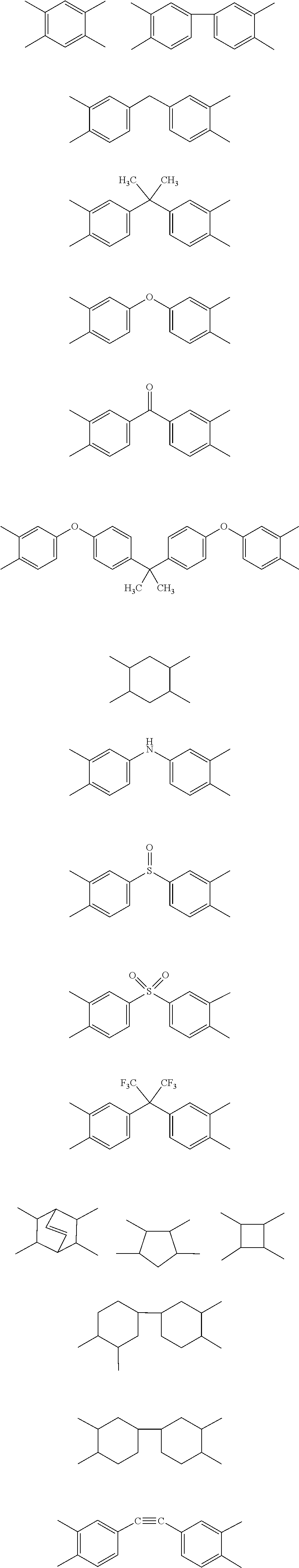
wherein bonds that are yet unbonded to substituent groups are to be bonded to carbonyl carbons forming cyclic imide structures in the formulae (1) and (2).

4. The curable resin composition according to claim 1, wherein the curable resin composition is of a heat curing type.

5. The curable resin composition according to claim 1, wherein the catalyst as the component (B) is at least one selected from the group consisting of a thermal radical polymerization initiator and an anionic polymerization initiator.

6. The curable resin composition according to claim 5, wherein the component (B) is an anionic polymerization initiator, and the curable resin composition further contains an epoxy resin having two or more epoxy groups per molecule.

7. The curable resin composition according to claim 1, wherein a cured product of the curable resin composition has a dielectric tangent of not larger than 0.005 at 10 GHz.

8. The curable resin composition according to claim 1, wherein a test piece obtained by laminating the curable resin composition on a copper foil having a surface roughness Ra of 0.17 μm, and then curing the curable resin composition by performing heating at 130° C. for 30 min and then at 170° C. for another 30 min, has a peeling strength of not lower than 0.8 kN/m between the cured product of the curable resin composition and the copper foil when measured in accordance with JIS C 6481, and has a peeling strength of not lower than 0.3 kN/m between the cured product and the copper foil after being left at 130° C. and 85% RH for 100 hours.

9. A bonding film comprising the curable resin composition according to claim 1.

10. A printed-wiring board having the bonding film according to claim 9.
